(19) United States
(12) Patent Application Publication
(10) Pub. No.: US 2026/0362730 A1
(43) Pub. Date: Nov. 12, 2026

(54) Casimir-Effect-Based Tunnel Transistor Using Graphene-Doped Conductors

(71) Applicant: Qubit Semiconductor LLC, Duxbury, MA (US)

(72) Inventor: Douglas Dannemiller, Duxbury, MA (US)

(21) Appl. No.: 19/202,232

(22) Filed: May 8, 2025

Related U.S. Application Data
(60) Provisional application No. 63/780,389, filed on Mar. 30, 2025.

(51) Int. Cl. H10D 30/40; H10D 62/80

(52) U.S. Cl. CPC H10D 30/402; H10D 62/882

(57) ABSTRACT

The invention introduces a tunnel transistor with a dynamically tunable gate potential, enabling rapid and low-power electronic state transitions without traditional electrostatic gating. It comprises a graphene-doped source and drain electrode, a vacuum tunneling barrier with a central graphene layer for controlled single electron tunneling, and a gate structure that alters the separation of the source and drain nano-electromechanical switching using Casimir force. By varying the distance between the source and drain, the device achieves single electron tunneling across the vacuum, preserving spin coherence. The vacuum environment mitigates decoherence caused by material barriers, while graphene doping enhances spin-orbit coupling, allowing the gate voltage to control tunneling and induce Rashba spin-orbit interactions. Varying the barrier width and the fermi level in the middle graphene layer controls the trapped electron's time and place, enabling initializing, manipulating, and reading out a qubit.

### FIELD OF THE INVENTION

The present invention relates to transistor technology and, more specifically, to a tunnel transistor that utilizes the Casimir effect to modulate electronic flow via graphene-doped conductive materials and a graphene layer that serves as quantum dot in a vacuum barrier.

### BACKGROUND OF THE INVENTION

As semiconductor devices approach the limits of miniaturization, traditional transistor architectures face challenges related to power efficiency, quantum tunneling leakage, and heat dissipation. The Casimir effect, which arises from quantum vacuum fluctuations between closely spaced conductive surfaces, presents an opportunity to develop novel transistor architectures that leverage this force for electronic switching.

Graphene-doped conductors exhibit exceptional electrical and mechanical properties, making them suitable for enhancing the stability and efficiency of nanoscale electronic components. By integrating the Casimir effect into transistor gate operation, this invention aims to create an energy-efficient and high-speed alternative to conventional field-effect transistors (FETs).

### SUMMARY OF THE INVENTION

The invention provides a tunnel transistor in which vacuum fluctuations induce a dynamically tunable gate potential. The transistor comprises:
A source and drain electrode composed of graphene-doped conductors.
A vacuum tunneling barrier situated between the source and drain, engineered to exploit the Casimir effect for gate modulation, with a central graphene layer enabling controlled single electron tunneling.
A gate structure that dynamically alters the separation of the source and drain by switching the casimir force, thereby controlling the electron tunneling probability.

By varying the distance between the source and drain with a vacuum tunneling barrier, the device enables rapid and low-power electronic state transitions without requiring traditional electrostatic gating mechanisms. With finely tuned gap separation single electron tunneling across the vacuum can be achieved creating preserved spin coherence. The vacuum environment mitigates decoherence that material conducting barriers create due to vibration.

The graphene doped conductors enhances spin-orbit coupling the gate voltage can control the tunneling and induce Rashba spin-orbit interactions. Varying the barrier width and the fermi level in a local area of the middle graphene layer can control the time and place of the trapped electron, effectively initializing, manipulating, and reading out a electron spin based qubit. The graphene doping enables electron spin control in the source and spin filtering on the drain. Spin dependent tunneling enables the readout of the quantum state of the electron and whether the electron had up or down spin.

### BRIEF DESCRIPTION OF THE DRAWINGS

FIG. 1: Casimir force actuated tunneling transistor with graphene doped conductors-open state

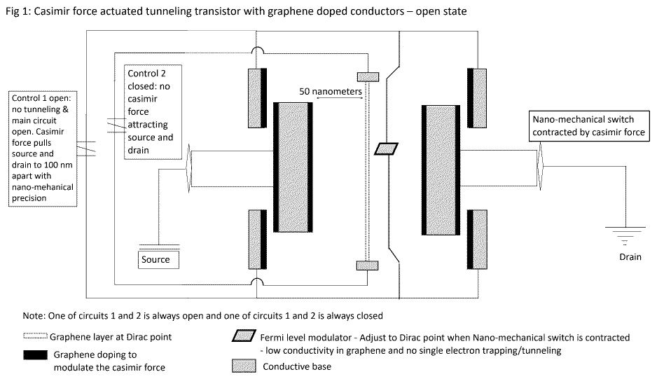

FIG. 2: Casimir force actuated tunneling transistor with graphene doped conductors-closed state

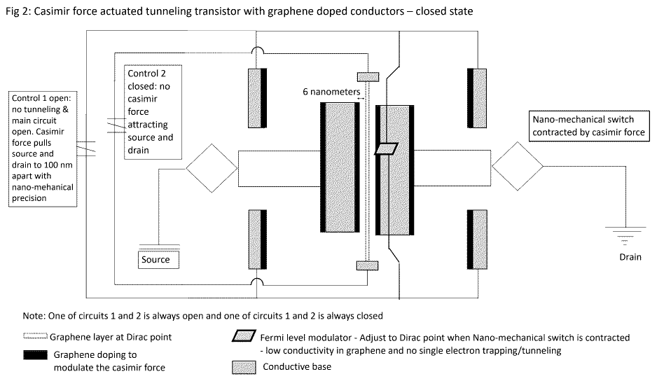

### DETAILED DESCRIPTION OF THE INVENTION

The proposed transistor operates by harnessing the Casimir force to regulate quantum tunneling. When the gate structure is adjusted, the Casimir force changes, modifying the potential landscape of the tunneling barrier. This modulation alters the probability of electron tunneling from the source to the drain, effectively switching the transistor on or off.

### 1. Materials and Fabrication

The source and drain electrodes are composed of graphene-doped conductors, providing high conductivity and low electron scattering. The tunneling barrier consists of a nanometer-scale insulating layer engineered to maximize sensitivity to Casimir forces.

1: A quantum tunneling transistor comprising:
a source electrode and a drain electrode comprising graphene-doped conductive materials, spaced to define a vacuum tunneling gap.
a suspended monolayer graphene gate electrode positioned above the vacuum tunneling gap, wherein said graphene gate is electrically coupled to a voltage source to dynamically modulate its surface conductivity, wherein modulation of the gate conductivity alters the Casimir force between the gate and the source electrode, thereby adjusting the effective tunneling barrier between the source and the drain; and wherein the monolayer graphene gate further comprises a laterally confined region defining a quantum dot configured to localize a single electron whose spin or charge state encodes quantum information.

2: The device of claim 1, wherein the quantum dot is formed by lateral electrostatic confinement applied to the suspended graphene sheet-fermi level local control.

3:The device of claim 1, wherein the gate voltage induces mechanical displacement of the graphene gate via Casimir attraction, thereby dynamically varying the tunneling gap between the gate and the source.

4: The device of claim 1, wherein the quantum state of the trapped electron is read out via spin-dependent tunneling between the source and the drain electrodes.

5: The device of claim 1, wherein the transistor is integrated into a low-power logic circuit.

6: The device of claim 1, wherein the transistor is implemented in a quantum computing architecture.
